(19) United States
(12) Patent Application Publication
(10) Pub. No.: US 2025/0157546 A1
(43) Pub. Date: May 15, 2025

(54) MEMORY STORAGE DEVICE AND READING METHOD THEREOF

(71) Applicant: Winbond Electronics Corp., Taichung City (TW)

(72) Inventor: Wen-Chiao Ho, Hsinchu County (TW)

(73) Assignee: Winbond Electronics Corp., Taichung City (TW)

(21) Appl. No.: 18/399,571

(22) Filed: Dec. 28, 2023

(30) Foreign Application Priority Data
Nov. 14, 2023 (TW) 112143811

(51) Int. Cl. G11C 16/26; G11C 16/14

(52) U.S. Cl. CPC G11C 16/26; G11C 16/14

(57) ABSTRACT

A memory storage device including a memory array and a sensing amplifier circuit is provided. The memory array includes a memory cell and a reference cell. During an erase phase, the memory cell and the reference cell are erased together. The sensing amplifier circuit is coupled to the memory array. During a reading phase, the sensing amplifier circuit compares a cell current of the memory cell with a reference current of the programmed reference cell to determine a state of the memory cell. In addition, a reading method for a memory storage device is also provided.

### CROSS-REFERENCE TO RELATED APPLICATION

This application claims the priority benefit of Taiwan application serial no. 112143811, filed on Nov. 14, 2023. The entirety of each of the above-mentioned patent applications is hereby incorporated by reference herein and made a part of this specification.

### BACKGROUND

### Technical Field

The invention relates to an electronic device and an operating method thereof, and in particular, to a memory storage device and a reading method thereof.

### Description of Related Art

In the prior art, memory arrays often require multiple loop operations to write data to memory cells. The loop operation includes an erase operation and a programing operation. The memory cells of the memory arrays may undergo cycling degradation due to multiple loop operations. The degraded memory cells will affect the current they provide, thus affecting the accuracy of reading the memory cells.

### SUMMARY

The present invention provides a memory storage device and a reading method thereof, which can prevent the memory storage device from being affected by cyclic degradation and affecting the accuracy of its reading.

The memory storage device of the present invention includes a memory array and a sensing amplifier circuit. The memory array includes a memory cell and a reference cell. During an erase phase, the memory cell and the reference cell are erased together. The sensing amplifier circuit is coupled to the memory array. During a reading phase, the sensing amplifier circuit compares a cell current of the memory cell with a reference current of the programmed reference cell to determine a state of the memory cell. In addition, a reading method for a memory storage device is also provided.

The reading method for a memory storage of the present invention includes: during an erase phase, performing an erase operation on the memory cell and the reference cell; performing a programming operation on the reference cell; and during a reading phase, comparing a cell current of the memory cell with a reference current of the programmed reference cell to determine a state of the memory cell.

In order to make the above-mentioned features and advantages of the present invention more obvious and easier to understand, embodiments are given below and are described in detail below with reference to the accompanying drawings.

### BRIEF DESCRIPTION OF THE DRAWINGS

FIG. 1 is a block diagram of a memory storage device according to an embodiment of the present invention.

FIG. 2 is a threshold voltage distribution diagram of a memory cell of the embodiment of FIG. 1.

FIG. 3 is a block diagram of a memory storage device according to another embodiment of the present invention.

FIG. 4 is a schematic diagram of a sensing amplifier circuit according to an embodiment of the present invention.

FIG. 5 is a schematic diagram of a reference current generating circuit according to an embodiment of the present invention.

FIG. 6 is a schematic diagram of a reading method for the memory storage device according to an embodiment of the present invention.

### DESCRIPTION OF THE EMBODIMENTS

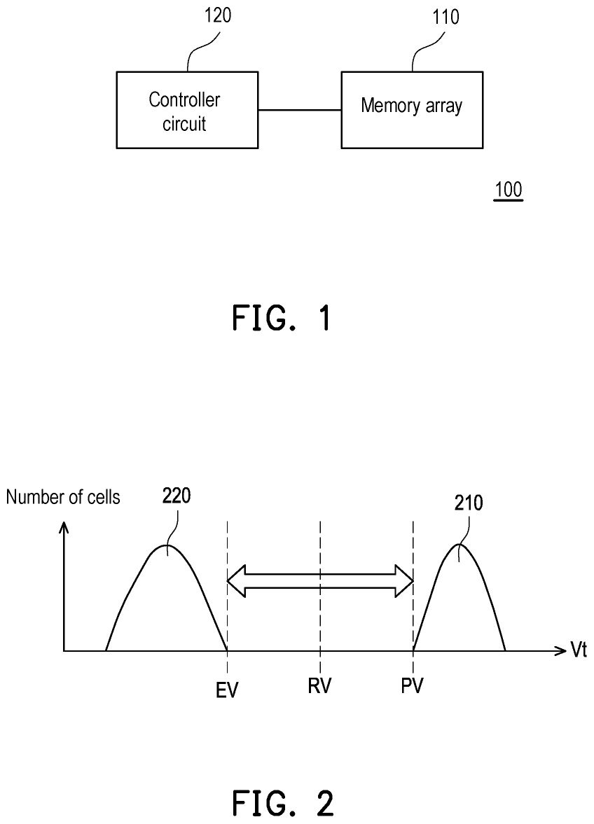

FIG. 1 is a block diagram of a memory storage device according to an embodiment of the present invention. FIG. 2 is a threshold voltage distribution diagram of a memory cell of the embodiment of FIG. 1. Referring to FIG. 1 and FIG. 2, the memory storage device 100 includes a memory array 110 and a controller circuit 120. The controller circuit 120 is coupled to the memory array 110. The controller circuit 120 is used to perform an erase operation, a programming operation and a reading operation on the memory array 110. The internal structure of the controller circuit 120 can be sufficiently taught, suggested, and implemented by persons with ordinary knowledge in the art.

Specifically, taking a flash memory as an example, the controller circuit 120 applies a specific voltage to a memory cell and completes the reading operation by sensing a cell current. Before performing the reading operation, the controller circuit 120 will perform the erase operation or the programming operation on the memory cell to make the memory cell have different threshold voltages.

Taking FIG. 2 as an example, through the erase operation or the programming operation, the memory cell of the flash memory may have two states. After the programming operation, the memory cell has a first state. The memory cell in the first state has a higher threshold voltage Vt, such as a first distribution curve 210 above a threshold voltage PV shown in FIG. 2, which is a bit value such as 0. After the erase operation, the memory cell has a second state. The memory cell in the second state has a lower threshold voltage Vt, such as a second distribution curve 220 below a threshold voltage EV shown in FIG. 2, which is a bit value such as 1. Where the interval between the threshold voltage EV and the threshold voltage PV is called a read window.

In general, when performing the reading operation, a sensing amplifier circuit may compare a reference current provided by a reference cell with the cell current of a target cell to determine the state of the target cell. In a related art, the reference cell with a threshold voltage RV may be used to provide the reference current as a basis for comparison. In the related embodiment, the interval between the threshold voltage EV and the threshold voltage RV is called a read “1” window; the interval between the threshold voltage RV and the threshold voltage PV is called a read “0” window. In order to ensure the accuracy of reading, the read “1” window and the read “0” window must be large enough. In addition, in a related art, since the distribution of the threshold voltage value of the memory cell may be changed due to cycling degradation, (such as the first distribution curve 210 above the threshold voltage PV and the second distribution curve 220 below the threshold voltage EV in FIG. 2), and the size of the read “1” window or the read “0” window is changed, thereby affecting the accuracy of reading.

In the embodiment, the memory cell higher than the threshold voltage PV can be used as the reference cell, which provides the reference current as a basis for comparison and can maximize the read window to the interval between the threshold voltage EV and the threshold voltage PV to ensure the accuracy of reading. Besides, in the embodiment, the reference cell and the target cell are configured in the same memory block. The reference cell and the target cell in the same memory block can perform a loop operation together, such as being erased together. Therefore, the reference cell and the target cell have similar cycling degradation levels, which can avoid affecting the accuracy of reading due to inconsistent cycling degradation levels between the memory cell and the reference cell.

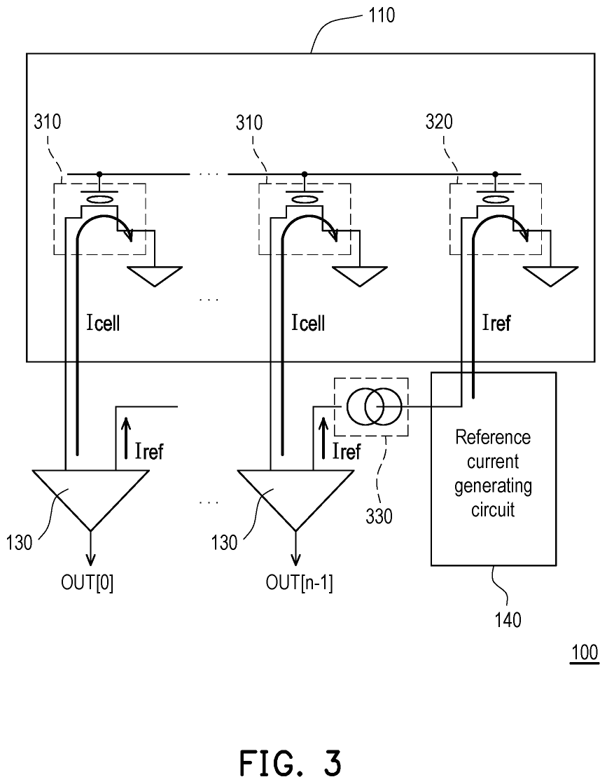

FIG. 3 is a block diagram of a memory storage device according to another embodiment of the present invention. Referring to FIG. 3, the memory storage device 100 includes a memory array 110, a sensing amplifier circuit 130 and a reference current generating circuit 140. The memory storage device 100 may also include the controller circuit 120 of FIG. 1. The memory array 110 includes multiple the memory cells 310 and a reference cell 320. During a reading phase, one or more memory cells 310 may be selected for reading.

The controller circuit 120 is coupled to the memory array 110. During an erase phase, the controller circuit 120 is used to perform an erase operation on the memory cell 310 and the reference cell 320. Therefore, during the erase phase, the memory cell 310 and the reference cell 320 are erased together. During a programming phase, the controller circuit 120 performs a programming operation on the reference cell 320 or the memory cell 310 to be written with a bit value of 0, so that the reference cell 320 has a threshold voltage value higher than the threshold voltage PV. For example, the reference cell 320 is programmed during a wafer test phase or after each erase operation.

The reference current generating circuit 140 is coupled to the memory array 110. During a reading phase, the reference current generating circuit 140 is used to provide the reference current Iref. In the embodiment, the reference current generating circuit 140 provides the reference current Iref to the sensing amplifier circuit 130 corresponding to the memory cell 310 in a current mirror manner, for example, through a current mirror circuit 330. The current mirror circuit 330 shown in FIG. 3 is only for illustration, and the structure of the current mirror circuit 330 can be implemented with current mirror structures well known in the art.

The sensing amplifier circuit 130 is coupled to the memory array 110. During the reading phase, the sensing amplifier circuit 130 compares a cell current Icell of the memory cell 310 and the reference current Iref of the programmed reference cell 320 to determine the state of the memory cell 310, and outputs the corresponding comparison result, such as OUT[0]˜OUT[n−1], where n is an integer greater than 1.

In the embodiment, the reference current Iref flows from the reference current generating circuit 140 to the reference cell 320 and then to ground. Therefore, the reference cell 320 draws the reference current Iref from the reference current generating circuit 140. Besides, the cell current Icell flows from the sensing amplifier circuit 130 to the memory cell 310 and then to ground. Therefore, the memory cell 310 draws the cell current Icell from the sensing amplifier circuit 130.

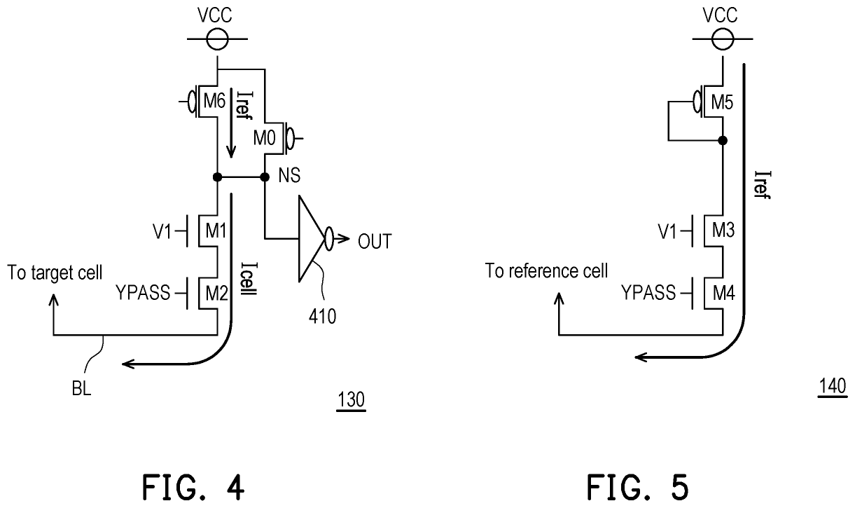

FIG. 4 is a schematic diagram of a sensing amplifier circuit according to an embodiment of the present invention. FIG. 5 is a schematic diagram of a reference current generating circuit according to an embodiment of the present invention. Referring to FIG. 4 and FIG. 5, the sensing amplifier circuit 130 includes a sensing node NS. During a precharge phase, since a transistor M0 is turned on, the sensing node NS is charged to a first voltage VCC.

On a transmission path of the cell current Icell, the sensing amplifier circuit 130 includes a transistor M1 and a transistor M2. The gate of the transistor M1 is connected to a clamp voltage V1 to limit the voltage of a bit line BL during the reading phase. The gate of the transistor M2 is connected to an address signal YPASS. The address signal YPASS is used to turn on the transistor M2 of the sensing amplifier circuit 130 corresponding to the target cell, so that the cell current Icell is passed from the transmission path to the target cell.

On the other hand, corresponding to the sensing amplifier circuit 130, the reference current generating circuit 140 includes a transistor M3 and a transistor M4. The transistor M3 and the transistor M4 operate similarly to the transistor M1 and the transistor M2 during the reading phase. Where the reference cell 320 can be programmed during a wafer test phase or after each erase operation, so that the reference current generating circuit 140 can provide the reference current Iref in the reading phase, which is equal to the current in the memory cell in a first state.

Additionally, a transistor M5 of the reference current generating circuit 140 and a transistor M6 of the sensing amplifier circuit 130 are current mirror circuits. The transistor M5 is used to mirror the reference current Iref to the transistor M6.

When the memory cell 310 is in the first state, the cell current Icell is equal to the reference current Iref. Therefore, during the reading phase, the voltage value of the sensing node NS may remain at a first voltage VCC. On the contrary, when the memory cell 310 is in a second state, the cell current Icell is greater than the reference current Iref. Therefore, during the reading phase, the voltage value of the sensing node NS may drop to a second voltage, wherein the second voltage is less than the first voltage VCC. Therefore, an inverter 410 may output the voltage level of the sensing node NS as a comparison result OUT.

In an embodiment, the memory chip may include multiple sectors. The capacity of each sector is, for example, 4 KB (kilobytes). Each sector has one or more reference cells, and the sector is a basic unit of erasure. The reference cell can be selected from the memory cell in the sector, or set separately in the sector. In addition, the reference cell can also be set in the middle or edge of the sector, and the present invention is not limited thereto.

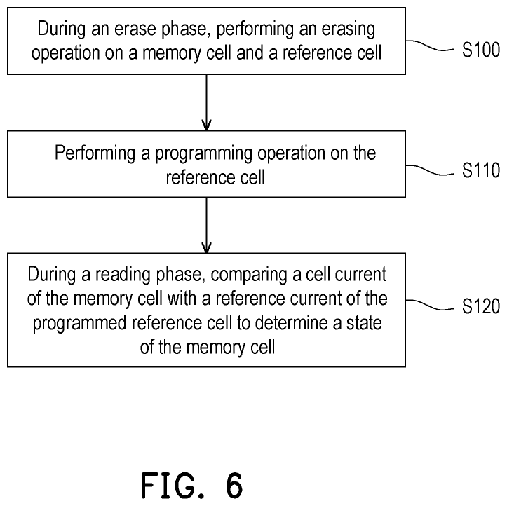

FIG. 6 is a schematic diagram of a reading method for the memory storage device according to an embodiment of the present invention. Referring to FIG. 1, FIG. 2 and FIG. 6, the reading method of the embodiment can be applied to, for example, the memory storage device 100 of FIG. 1 and FIG. 2, and the present invention is not limited thereto. Taking the memory storage device 100 of FIG. 1 and FIG. 2 as an example, in step S100, during the erase phase, the controller circuit 120 performs the erase operation on the memory cell 310 and the reference cell 320. In step S110, the controller circuit 120 performs the programming operation on the reference cell 320. In step S120, during the reading phase, the cell current Icell of the memory cell 310 is compared with the programmed reference current Iref of the reference cell 320 to determine the state of the memory cell 310.

Additionally, the reading method for the memory storage device of the embodiment of the present invention can obtain sufficient teachings, suggestions and implementation instructions from the description of the embodiments from FIG. 1 to FIG. 5.

In summary, in the embodiments of the present invention, the reference current provided by the reference cell can maximize the read window to ensure the accuracy of the reading. Besides, the reference cell and the target cell in the memory block can perform cycling operations together, so the reference cell and the target cell have similar cycling degradation, which can avoid the impact of cycling degradation on the accuracy of reading.

Although the present application has been disclosed as above with embodiments, it is not intended to limit the present application. Any person with ordinary knowledge in the art, without departing from the spirit and scope of the present application, can make some changes. Therefore, the protection scope of the present application shall be determined by the scope of the claims.

What is claimed is:

1. A memory storage device, comprising:
a memory array, comprises a memory cell and a reference cell, wherein the memory cell and the reference cell are erased together during an erase phase; and
a sensing amplifier circuit, coupled to the memory array, and the sensing amplifier circuit compares a cell current of the memory cell with a reference current of the programmed reference cell to determine a state of the memory cell during a reading phase.

2. The memory storage device according to claim 1, further comprises:
a controller circuit, coupled to the memory array, wherein in the erase phase, the controller is configured to perform an erase operation on the memory cell and the reference cell, and the controller circuit performs a programming operation on the reference cell.

3. The memory storage device according to claim 1, further comprises:
a reference current generating circuit, coupled to the memory array, and during the reading phase, the reference current generating circuit is configured to provide the reference current.

4. The memory storage device according to claim 3, wherein the reference current generating circuit provides the reference current to the sensing amplifier circuit corresponding to the memory cell through a current mirror circuit.

5. The memory storage device according to claim 3, wherein the reference cell draws the reference current from the reference current generating circuit.

6. The memory storage device according to claim 1, wherein the memory cell draws the cell current from the sensing amplifier circuit.

7. The memory storage device according to claim 1, wherein the reference cell is programmed during a wafer test phase or after each erase operation.

8. The memory storage device according to claim 1, wherein the sensing amplifier circuit comprises a sensing node, and the sensing node is charged to the first voltage during a precharge phase.

9. The memory storage device according to claim 8, wherein when the memory cell is in a first state, the cell current is equal to the reference current, and a voltage value of the sensing node remains at the first voltage.

10. The memory storage device according to claim 8, wherein when the memory cell is in the second state, the cell current is greater than the reference current, and the voltage value of the sensing node drops to a second voltage, where the second voltage is less than the first voltage.

11. A reading method for a memory storage device, wherein the memory storage device comprises a memory array, and the memory array comprises a memory cell and a reference cell, the reading method comprises:
during an erase phase, performing an erase operation on the memory cell and the reference cell;
performing a programming operation on the reference cell; and
during a reading phase, comparing a cell current of the memory cell with a reference current of the programmed reference cell to determine a state of the memory cell.

12. The reading method for the memory storage device according to claim 11, further comprises:
providing the reference current by current mirroring.

13. The reading method for the memory storage device according to claim 11, wherein the reference cell draws the reference current from a reference current generating circuit.

14. The reading method for the memory storage device according to claim 11, wherein the memory cell draws the cell current from a sensing amplifier circuit.

15. The reading method for the memory storage device according to claim 11, wherein the reference cell is programmed during a wafer test phase or after each erase operation.

16. The reading method for the memory storage device according to claim 11, wherein the sensing amplifier circuit comprises a sensing node, and the reading method further comprises:
charging the sensing node to a first voltage during a precharge phase.

17. The reading method for the memory storage device according to claim 16, wherein when the memory cell is in a first state, the cell current is equal to the reference current, and a voltage value of the sensing node remains at the first voltage.

18. The reading method for the memory storage device according to claim 11, wherein when the memory cell is in the second state, the cell current is greater than the reference current, and the voltage value of the sensing node drops to a second voltage, where the second voltage is less than the first voltage.
